(19) United States
(12) Patent Application Publication
(10) Pub. No.: US 2012/0018709 A1
(43) Pub. Date: Jan. 26, 2012

(54) ORGANIC ELECTROLUMINESCENCE ELEMENT AND METHOD OF MANUFACTURE OF SAME

(75) Inventor: Yutaka Terao, Nagano (JP)

(73) Assignee: FUJI ELECTRIC CO., LTD., Kawasaki-shi (JP)

(21) Appl. No.: 13/143,930

(22) PCT Filed: Apr. 14, 2009
(86) PCT No.: PCT/JP2009/057484

§ 371 Date: Sep. 29, 2011

(51) Int. Cl. H01L 51/52; H01L 51/56

(52) U.S. Cl. 257/40; 438/46; 257/E51.018; 257/E51.024

(57) ABSTRACT

An organic EL element, includes, in the order recited: a supporting substrate; an anode; an organic EL layer and having provided thereon, in the order recited: a hole transport layer; a light emission layer; an electron transport layer; and an electron injection layer, in which the hole transport layer, the light emission layer, and the electron transport layer are composed of organic materials, and the electron injection layer is composed of an n-type chalcogenide semiconductor having an optical band gap of 2.1 eV or greater; and a cathode provided on the organic EL layer and composed of a transparent conductive oxide. The organic EL element is a low-voltage, high-efficiency top-emission type or transparent organic EL element. Disclosed also is a method of manufacturing the organic EL element includes forming the electron injection layer by a physical vapor phase growth method that is free of plasma discharge.

### BACKGROUND OF THE INVENTION

1. Field of the Invention

An object of the present invention is to provide an organic electroluminescence element (hereafter also called an organic EL element) and a method of manufacture of such an element. In particular, an object is to provide a transparent organic EL element (and in particular a top-emission type organic EL element) with high light emission efficiency and low power consumption, and a method of manufacture of such an element. This organic EL element can be applied in light sources for flat panel displays and illumination, and in particular in active matrix (AM) driven organic EL displays and organic EL illumination.

2. Background of the Related Art

Organic EL elements can achieve high current densities at low voltages, and therefore can realize high light emission brightness and light emission efficiency, and in recent years organic EL elements have already been commercialized in applications to flat panel displays such as liquid crystal displays, and are anticipated to find uses in light sources for illumination as well.

Such organic EL elements at least include an organic EL layer including a light emission layer, and an anode and cathode which sandwich the organic EL layer. The electrode on the side on which light is extracted must have high transmissivity for EL light from the light emission layer. As the material used to form the electrode on the light extraction side, normally such transparent conductive oxide materials as indium tin oxide (ITO), indium zinc oxide (IZO), indium tungsten oxide (IWO), and similar are used. Since these transparent conductive oxide materials have a comparatively high work function of approximately 5 eV, they are used as electrodes (anodes) for hole injection into an organic material.

Light emission from an organic EL element is obtained when holes injected into the highest occupied molecular orbital (HOMO, generally measured as the ionization potential) of the light emission layer material, and electrons injected into the lowest unoccupied molecular orbital (LUMO, generally measured as the electron affinity), recombine, the excitation energy of excitons generated as a result is relaxed, and light is emitted as a result. In order to enable efficient hole injection and electron injection into the light emission layer, an organic EL element employs a stacked structure which, in addition to the light emission layer, uses some or all of a hole injection layer, hole transport layer, electron transport layer, and electron injection layer.

In the prior art, organic EL elements have generally been of the type in which light is extracted from the supporting substrate side (bottom-emission type), formed by forming on a transparent supporting substrate an anode of ITO as a lower electrode, and thereupon forming in sequence as the organic EL layer a hole injection/transport layer, light emission layer, electron injection/transport layer, and similar and then forming a cathode comprising Al or another metal film as an upper electrode.

However, among flat panel display applications in recent years, AM driven organic EL displays in which switching elements employing thin film transistors (TFTs) comprising amorphous Si or polysilicon for each pixel are provided, with the organic EL element formed thereabove, have become the mainstream.

In this case, switching elements are opaque, and so there is the problem that the pixel aperture ratio (light emission area) is reduced. As means of preventing this lowering of the pixel aperture ratio, it has become desirable to apply organic EL elements of the type in which the upper electrodes are made transparent and light is extracted from the film deposition side (top-emission type).

When the upper electrode is made transparent, there is a choice of using a lower reflective electrode as the anode, forming in sequence a hole injection/transport layer, light emission layer and electron injection/transport layer, and using the upper transparent electrode as the cathode (see Non-patent Reference 1), and there is another choice of using a lower reflective electrode as the cathode, forming thereupon in sequence an electron injection/transport layer, light emission layer, and hole injection/transport layer, and using the upper transparent electrode as the anode (see Non-patent Reference 2).

In particular, when polysilicon TFTs are used as switching elements, generally the lower electrode is made the anode in view of the switching circuit configuration, and so there are increased demands made on the cathode as the upper transparent electrode.

A metal thin film of Mg—Ag alloy or similar is sometimes used as the upper transparent cathode. However, an upper transparent electrode using a metal thin film has the problem that metals absorb visible light to some extent, so that the light emission intensity is reduced; further, the high reflectivity is accompanied by a microcavity effect, and there is the problem that the film thickness distribution of the organic layer determining the distance between the lower reflective electrode and the metal thin film must be controlled extremely precisely. Hence there has been a desire to use the transparent conductive oxide materials which in the prior art have been employed in anodes, as upper transparent cathodes.

When a transparent conductive oxide material is deposited on an organic EL layer by sputtering or another method, there is the concern that an organic light emission layer material and/or electron injection/transport material is easily oxidized. Oxidation of such materials causes function degradation, and there is the concern that the light emission efficiency of the organic EL element may be significantly worsened.

As a method of resolving this problem of degradation due to oxidation of the organic EL layer, a method has been used of providing a damage relaxation layer between the electrode comprising a transparent conductive oxide material and the electron transport layer. As a damage relaxation layer, an extremely thin film of an Mg—Ag alloy which has been used as a cathode material (see Non-patent Reference 1), and a thin film of copper phthalocyanine (CuPc) (see Non-patent Reference 3) have been proposed.

On the other hand, a method has also been proposed in which, by providing an electron injection layer comprising an inorganic material on the electron transport layer, damage due to a sputtering method is prevented (see Patent Reference 1).

Further, a method has been proposed which applies a hole injection/transport layer and/or electron injection/transport layer comprising an inorganic semiconductor as the charge injection/transport layers of an organic EL element (see Patent References 2 to 7). The techniques described in Patent References 2 to 7 were proposed in view of the problems at that time with organic EL elements described below.

Organic semiconductors are intrinsic semiconductors, and have extremely low charge densities compared with inorganic semiconductors. Further, organic semiconductors also have low charge mobilities, so that electrical conductivity is low, and the driving voltage of an organic EL element must be made high.

Organic semiconductor materials have poor heat resistance, and so are lacking in reliability and/or thermal stability.

When an inorganic semiconductor layer is applied to a top-emission type or transparent organic EL element, an inorganic semiconductor layer is formed on the side on which light is extracted, seen from the light emission layer, and so there is a need for transparency with respect to visible light, or at least the light radiated from the light emission layer; and from this standpoint, SiC, SiN, a-C (amorphous carbon), oxide semiconductors, II-VI group compound semiconductors, III-V group compound semiconductors, and similar are preferable for use.

Patent Reference 1: Japanese Patent Application Laid-open No. 2000-340364; Patent Reference 2: Japanese Patent Application Laid-open No. S62-76576; Patent Reference 3: Japanese Patent Application Laid-open No. H1-312874; Patent Reference 4: Japanese Patent Application Laid-open No. H2-196475; Patent Reference 5: Japanese Patent Application Laid-open No. H3-77299; Patent Reference 6: Japanese Patent Application Laid-open No. H3-210792; and Patent Reference 7: Japanese Patent Application Laid-open No. H11-149985.

Non-patent Reference 1: Nature, Vol. 380 (Mar. 7, 1996), p. 29; Non-patent Reference 2: Applied Physics Letters, Vol. 70 Iss. 22 (Jun. 2, 1997), p. 2954; and Non-patent Reference 3: Applied Physics Letters, Vol. 72 Iss. 17 (Apr. 27, 1998), p. 2138.

In a method of using a metal thin film as a damage relaxation layer (Non-patent Reference 1), the film thickness of the metal thin film must be made thick in order to obtain an adequate damage relaxation effect. However, if the film thickness of the metal thin film is made thick, the problem arises that light from the light emission layer is absorbed. The method of using CuPc as a damage relaxation layer (Non-patent Reference 3) alleviates the problem of light absorption in the damage relaxation layer. However, electron injection characteristics from an electron transport layer into CuPc are insufficient, and so there are the problems that the element driving voltage increases and moreover that light emission efficiency declines.

Further, in a method in which damage due to a sputtering method is prevented by providing an electron injection layer comprising an inorganic material on an electron transport layer (Patent Reference 1), the inorganic electron injection layer is an alkali metal oxide, alkali earth metal oxide, or oxide of a lanthanoid system element, and the electrical conductivity of the inorganic electron injection layer itself is not high. Hence there is the problem of a tradeoff between the effect of making the film thin and lowering the element driving voltage, and the effect of making the film thick and relaxing damage to the electron transport layer. Further, depending on the method of formation, there is the concern that as before, oxidation degradation of the organic electron transport layer adjacent to the inorganic electron injection layer may occur.

Further, in application to a top-emission type or transparent organic EL element, in a method which uses SiC, SiN, or a-C as the inorganic semiconductor layer (Patent References 2 to 7), a plasma-enhanced chemical phase vapor deposition (PECVD) method or sputtering method is normally used in formation. Hence there is the problem that the organic EL layer including the light emission layer may be degraded as a result of exposure to plasma during inorganic semiconductor layer formation.

Further, when an oxide semiconductor is used as an inorganic semiconductor layer, often the valence band, which is energy levels of conduction electrons of the oxide semiconductor, are much lower than the lowest unoccupied molecular orbital (LUMO) which is the energy level of conduction electrons of an organic light emission layer or organic electron transport layer. As a result, the potential barrier for electron transport at the organic layer/inorganic semiconductor layer interface is high, the driving voltage rises, and often practical application is difficult. In addition, due to oxygen supplied during formation of an oxide semiconductor layer, there is the problem that oxidation degradation of the underlying organic layer occurs.

### SUMMARY OF THE INVENTION

The present invention was devised in light of the above-described issues, and provides a top-emission type or transparent organic EL element in which there is no oxidation degradation of the organic functional layer even when an upper cathode, comprising a transparent conductive oxide, is formed by sputtering or another method, and which moreover has a low driving voltage and high efficiency.

That is, the present invention provides an organic EL element, comprising, in the order recited: a supporting substrate; an anode provided on the supporting substrate; an organic EL layer provided on the anode and having provided thereon, in the order recited: a hole transport layer; a light emission layer; an electron transport layer; and an electron injection layer, in which the hole transport layer, the light emission layer, and the electron transport layer are comprised of organic materials, and the electron injection layer is comprised of an n-type chalcogenide semiconductor having an optical band gap of 2.1 eV or greater; and a cathode provided on the organic EL layer and comprised of a transparent conductive oxide.

Further, the present invention provides a method of manufacturing the organic EL element described above, comprising: forming the electron injection layer by a physical vapor phase growth method that is free of plasma discharge, that is, that does not use plasma discharge.

In an organic EL element configured as described above, an inorganic semiconductor layer comprising an n-type chalcogenide semiconductor is formed between an electron transport layer comprising an organic material and an upper cathode, so that even when a transparent conductive oxide is formed by a sputtering method as the upper cathode, oxidation degradation of the light emission layer and electron transport layer is prevented. In addition, degradation of the light emission layer and electron transport layer during formation of an inorganic semiconductor layer does not occur. Further, the n-type chalcogenide semiconductor electron injection layer efficiently pulls electrons from the transparent oxide cathode, and by disposing an organic electron transport layer between the light emission layer and the n-type chalcogenide semiconductor electron injection layer, lowering of the electron transport barrier from the electron injection layer to the light emission layer, and the ability to impede hole injection from the light emission layer into the electron injection layer can be imparted, so that a low-voltage, high-efficiency top-emission type or transparent organic EL element can be realized.

### BRIEF DESCRIPTION OF THE DRAWINGS

FIG. 1 shows in summary an example of an organic EL element of the invention.

### DETAILED DESCRIPTION OF THE INVENTION

The invention is explained below with reference to the drawing.

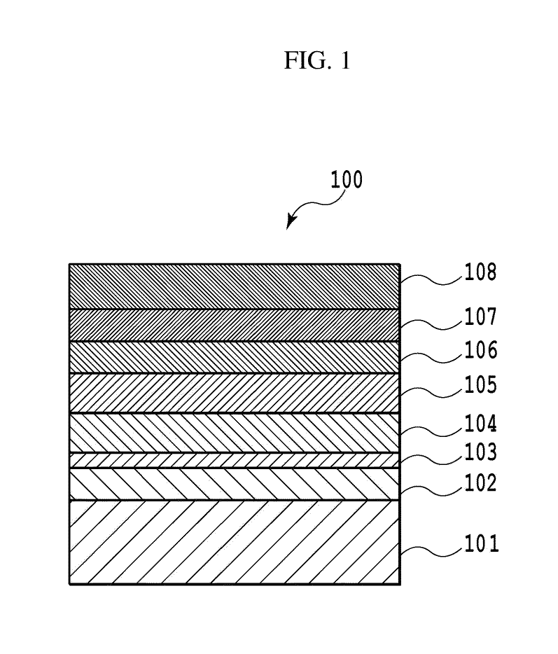

FIG. 1 is a schematic diagram showing an example of the configuration of an organic EL element 100 of the present invention. The organic EL element 100 shown in FIG. 1 has a stacked structure in which are stacked, in order on a substrate 101, an anode 102, hole injection layer 103, hole transport layer 104, light emission layer 105, electron transport layer 106, electron injection layer 107, and cathode 108. This layer configuration is similar to structures described in the prior art.

However, although an organic EL element of the present invention is a top-emission type or transparent organic EL element, the cathode is optically transmissive, and comprises a transparent conductive oxide material. In the case of a top-emission type element, light radiated from the light emission layer passes through the cathode and is perceived. And in the case of a transparent organic EL element in which the anode also comprises a transparent conductive oxide material, the anode is also optically transmissive, and light radiated from the light emission layer is perceived on both the anode side and on the cathode side.

In FIG. 1, the hole injection layer 103 is provided to promote injection of holes from the anode 102 into the hole transport layer 104, but a hole injection layer 103 is not necessarily required.

Further, similarly to cases in the prior art in which an inorganic semiconductor is used in the electron injection layer 107, when an n-type chalcogenide semiconductor is used in the electron injection layer 107, omission of an electron transport layer 106 comprising an organic material, and forming the electron injection layer 107 directly on the light emission layer 105, is also conceivable. However, in this case such problems as an increase in driving voltage and decline in light emission efficiency often occur. This is because two functions are demanded of the electron transport layer 106 adjacent to the light emission layer 105 in an organic EL element: 1) the function of efficiently injecting electrons into the light emission layer 105, and 2) the function of impeding holes moving from the light emission layer 105 in the direction of the cathode 108. However, in an electron injection layer 107 using an n-type chalcogenide semiconductor, because it is difficult to simultaneously realize these functions, the above-described problems arise.

Hence in the present invention, it is necessary to provide an electron transport layer 106 comprising an organic material between the light emission layer 105 and the electron injection layer 107 comprising an n-type chalcogenide semiconductor. The organic material forming the electron transport layer 106 can be selected together with the light emission layer material from among various materials described in detail below, and the problems of a decline in light emission efficiency and rise in driving voltage can be resolved.

Details of each layer are explained in the following.

### Substrate:

Substrates 101 which can be used in the present invention include, in addition to alkali glass substrates used in general flat panel displays and non-alkali glass substrates, silicon substrates, polycarbonate and other plastic substrates, plastic film, insulating films formed on stainless steel leaf, and similar. When manufacturing a top-emission type organic EL element, there is no need in particular for the substrate 101 to be transparent. On the other hand, when manufacturing a transparent organic EL element, an optically transmissive substrate must be used.

In the case of a substrate of a plastic material or similar with gas permeability, and in particular with permeability with respect to water vapor and/or oxygen, a film having gas barrier functions must be formed separately from the substrate.

Anode:

The anode 102 used in an organic EL element of the present invention may be optically transmissive or optically reflective. When the anode 102 is made optically transmissive, widely known transparent conductive oxide materials such as ITO (indium-tin oxide), IZO (indium-zinc oxide), IWO (indium-tungsten oxide), AZO (Al-doped zinc oxide), GZO (Ga-doped zinc oxide), and similar can be used. Further, poly-(3,4-ethylene dioxythiophene):poly-(styrene sulfonate) (PEDOT:PSS) or another highly conductive polymer material can be used.

When manufacturing a top-emission type organic EL element, the anode 102 can be a single metal material which is optically reflective, or can be a stacked structure of a transparent conductive oxide material as described above and an optically reflective metal material. Further, an optically reflective layer comprising a metal film may be formed on the substrate 101, and an anode 102 comprising a transparent conductive oxide material formed thereupon with an insulating layer interposed, in a configuration which prevents electrical connection of the optically reflective layer and the anode 102.

As the metal material used to form an optically reflective anode 102 or optically reflective layer, a highly reflective metal, amorphous alloy or microcrystalline alloy, or a stacked member of these, can be used. Highly reflective metals include Al, Ag, Ta, Zn, Mo, W, Ni, and Cr. Highly reflective amorphous alloys include NiP, NiB, CrP, and CrB. Highly reflective microcrystalline alloys include NiAI and silver alloys.

Organic EL layer:

In the configuration shown in FIG. 1, the organic EL layer is formed by stacking in order, from the side of the anode 102, a hole injection layer 103, hole transport layer 104, light emission layer 105, electron transport layer 106, and electron injection layer 107. As explained above, the hole injection layer 103 is a layer which may be optionally provided.

Hole Injection Layer:

Materials which can be used in the hole injection layer 103 of an organic EL element of the present invention include hole transport layers generally used in organic EL elements or organic TFT elements, such as materials having triarylamine partial structures, carbazole partial structures, oxadiazole partial structures, and similar.

Specifically, for example N,N′-diphenyl-N,N′-bis(3-methylphenyl)-1,1′-biphenyl-4,4′-diamine (TPD); N,N,N′,N′-tetrakis(4-metoxyphenyl)-benzidine (MeO-TPD); 4,4′,4″-tris{1-naphthyl(phenyl)amino}triphenylamine (1-TNATA); 4,4′,4″-tris{2-naphthyl(phenyl)amino}triphenylamine (2-TNATA); 4,4′,4″-tris(3-methylphenyl phenylamino)triphenylamine (m-MTDATA); 4,4′-bis{N-(1-naphthyl)-N-phenylamino}biphenyl (NPB); 2,2′,7,7′-tetrakis(N,N-diphenylamino)-9,9′-spiro-bifluorene (Spiro-TAD); N,N′-di(biphenyl-4-yl)-N,N′-diphenyl-(1,1′-biphenyl)-4,4′-diamine (p-BPD); tri(o-terphenyl-4-yl)amine (o-TTA); tri(p-terphenyl-4-yl)amine (p-TTA); 1,3,5-tris[4-(3-methylphenyl phenylamino)phenyl]benzene (m-MTDAPB); 4,4′,4″-tris-9-carbozolyltriphenylamine (TCTA); and similar can be used to form the hole injection layer 103.

Further, in addition to these widely used materials, materials with hole transport properties commercially marketed by various organic electronic material manufactures can be used to form the hole injection layer 103.

Further, an electron-accepting dopant may be added (p-type doping) to the hole injection layer 103. Electron-accepting dopants are for example tetracyanoquino dimethane derivatives and other organic semiconductors, and specifically, 2,3,5,6-tetrafluoro-7,7,8,8-tetracyanoquino dimethane (F₄-TCNG) and similar. Further, molybdenum oxide (MoO₃), tungsten oxide (WO₃), vanadium oxide (V₂O₅), and other inorganic semiconductors can also be used as electron-accepting dopants.

Hole Transport Layer:

Materials which can be used in the hole transport layer 104 of an organic EL element of the present invention can be freely selected from among publicly known materials used as hole transport materials in organic EL elements or organic TFTs, as in the abovementioned examples for hole injection layers. In general, from the standpoint of promoting properties for hole injection into the light emission layer 105, materials are preferable which satisfy the relation

Wa≦Ip(HIL)<Ip(HTL)<Ip(EML),

where Wa is the work function of the anode 102, Ip (HIL) is the ionization potential of the hole injection layer 103, Ip (HTL) is the ionization potential of the hole transport layer 104, and Ip (EML) is the ionization potential of the light emission layer 105.

Light Emission Layer:

The material of the light emission layer 105 can be selected according to the desired hue; for example, materials used to obtain emitted light with a blue to blue-green color include fluorescent whiteners such as benzothiazole compounds, benzo imidazole compounds, and benzo oxazole compounds; styryl benzene compounds; aromatic dimethyldiene compounds; and similar. Specifically, as materials emitting from blue to blue-green light, 9,10-di(2-naphthyl)anthracene (ADN); 4,4′-bis(2,2′-diphenylvinyl)biphenyl (DPVBi); 2-methyl-9,10,di(2-naphthyl)anthracene (MADN); 9,10-bis-(9,9-bis(n-propyl)fluorene-2-yl)anthracene (ADF); 9-(2-naphthyl)-10-(9,9-bis(n-propyl)-fluorene-2-yl)anthracene (ANF); and similar can be used.

The light emission layer 105 may be doped with a fluorescent dye; dye materials used as light emission dopants can be selected according to the desired hue. Specifically, as light emission dopants, materials known in the prior art such as perylene, rubrene and other fused ring derivatives; quinacridone derivatives; phenoxazone 660, 4-(dicyanomethylene)-2-methyl-6-(p-dimethylamino styryl)-4H-pyrane (DCM), 4-dicyanomethylene-6-methyl-2-[2-(julolidine 9-yl)ethyl]-4H-pyrane (DCM2), 4-(dicyanomethylene)-2-methyl-6-(1,1,7,7-tetramethyl julolidyl-9-enyl)-4H-pyrane (DCJT), 4-(dicyanomethylene)-2-t-butyl-6-(1,1,7,7-tetramethyl julolidyl-9-enyl)-4H-pyrane (DCJTB) and other dicyanomethylene derivatives; perinone, coumarin derivatives, pyrromethene derivatives, cyanine dyes, and similar can be used.

Further, in the present invention, in order to adjust the hue of the emitted light, a plurality of light emission dopants can be added into the same light emission layer material.

Electron Transport Layer:

In the present invention, the electron transport layer 106 provided between the light emission layer 105 and the electron injection layer 107 comprising an n-type chalcogenide semiconductor is important for eliciting device performance. It is preferable that the electron transport layer 106 be formed using material with excellent electron transport properties selected from among widely-known organic electron transport materials. Further, it is desirable that the electron affinity of the material forming the electron transport layer 106 take a value between the electron affinity of the material forming the light emission layer 105, land the electron affinity of the n-type chalcogenide semiconductor forming the electron injection layer 107. And, it is desirable that the ionization potential Ip (ETL) of the electron transport layer 106 be greater than the ionization potential Ip (EML) of the light emission layer 105.

Specifically, such electron transport materials include triazole derivatives such as 3-phenyl-4-(1′-naphthyl)-5-phenyl-1,2,4-triazole (TAZ); oxadiazole derivatives such as 1,3-bis[(4-t-butylphenyl)-1,3,4-oxadiazole]phenylene (OXD-7), 2-(4-biphenylyl)-5-(4-t-butylphenyl)-1,3,4-oxadiazole (PBD), and 1,3,5-tris(4-t-butylpheny-1,3,4-oxadiazolyl)benzene (TPOB); thiophene derivatives such as 5,5′-bis(dimesitylboryl)-2,2′-bithiophene (BMB-2T) and 5,5′-bis(dimesitylboryl)-2,2′:5′,2′-terthiophene (BMB-3T); aluminum complexes such as aluminum tris(8-quinolinolate) (Alq₃); phenanthroline derivatives such as 4,7-diphenyl-1,10-phenanthroline (BPhen) and 2,9-dimethyl-4,7-diphenyl-1,10-phenanthroline (BCP); and, silole derivatives such as 2,5-di-(3-biphenyl)-1,1-dimethyl-3,4-diphenyl silacyclopentadiene (PPSPP), 1,2-bis(1-methyl-2,3,4,5-tetraphenyl silacyclopentadienyl ethane (2PSP), and 2,5-bis-(2,2-bipyridine-6-yl)-1,1-dimethyl-3,4-diphenyl silacyclopentadiene (PyPySPyPy).

Electron Injection Layer:

In the present invention, an inorganic semiconductor layer comprising an n-type chalcogenide semiconductor is used as the electron injection layer 107. As explained below, the cathode 108 provided on the electron injection layer 107 comprises a transparent conductive oxide material, and is deposited by a sputtering method, by a reactive plasma film deposition method, or similar. When using the inorganic material as the electron injection layer 107, it is possible to avoid imparting damage to the electron transport layer 106 comprising an organic material adjacent to the electron injection layer 107, or to the light emission layer 105, attributed to the sputtering method or plasma film deposition method during deposition of the cathode 108. Further, oxidation degradation of organic layers (the electron transport layer 106 and light emission layer 105) can be prevented.

Further, in the present invention a chalcogenide semiconductor is selected from among inorganic semiconductors as the electron injection layer 107. Among publicly known materials in documents of the prior art, organic layers can be protected during cathode formation using Si, SiC, SiN, group III-V semiconductors, amorphous carbon (a-C), and other inorganic materials; but when depositing films of these inorganic materials, a film deposition method in which the substrate is not heated must be adopted in order to prevent crystallization of the organic layers. Such film deposition methods include PECVD, sputtering, and other methods. However, there are serious concerns that such film deposition methods may impart damage to the underlying organic layers due to plasma exposure, making such methods unsuitable.

Further, use of an oxide semiconductor which can be formed by evaporation deposition or similar method as the electron injection layer 107 is also conceivable; but as explained above, oxide semiconductors have the problems of a higher driving voltage due to an increased electron transport potential barrier at the interface of the electron injection layer 107 and electron transport layer 106, and oxidation degradation of the underlying organic layers caused by oxygen during film formation.

On the other hand, n-type chalcogenide semiconductors have the features that 1) oxidation of underlying organic layers during electron injection layer deposition does not readily occur; 2) a plasma process is not used, and moreover formation is possible without heating the substrate; and 3) often the conduction band levels are more shallow than for oxides, so that matching with the LUMO of the organic electron transport layer is easy. Further, the electronegativity of metal elements forming chalcogenide semiconductors, such as Se, Se and Te, are respectively 2.58, 2.55 and 2.1, which are low compared with the 3.44 of O. Hence oxidation degradation of underlying organic layers is much less likely to occur, and degradation of the characteristics of the organic EL element can be prevented. By using an n-type chalcogenide semiconductor, an electron injection layer 107 with excellent properties for electron injection into an adjacent organic electron transport layer 106 or light emission layer 105 can be obtained. For the above reasons, in the present invention an n-type chalcogenide semiconductor is used as the electron injection layer 107.

Further, many n-type chalcogenide semiconductors used in solar cells and similar have a narrow optical band gap, and absorb visible light. Hence in order to efficiently extract EL light to outside the element, it is important that there be little absorption in the emission band of the light emission layer 105. By using a chalcogenide semiconductor with an optical band gap of 2.1 eV or greater, absorption in the emission band of the light emission layer 105 can be suppressed. The preferred conditions of this requirement change depending on the emission color of the organic EL element; in the case of a red light emission element, a band gap of 2.1 eV or higher is sufficient, but in the case of a green light emission element a band gap of 2.4 eV or higher, and in the case of a blue light emission element a band gap of 2.6 eV or higher, is more preferable.

As specific n-type chalcogenide semiconductors, zinc sulfide (ZnS), manganese sulfide (MnS), and zinc manganese sulfide (MnₓZn₁₋ₓS) which is a mixture of these, or these materials with Se or Te substituted for S, can be used. In addition, a rare earth n-type chalcogenide semiconductor comprising any one among lanthanum sulfide (LaS), cerium sulfide (CeS), praseodymium sulfide (PrS), and neodymium sulfide (NdS), or any of these materials with Se or Te substituted for S, or a mixed composition of any of these, can preferably be used.

Further, it is preferable that an impurity serving as n-type dopant be added to the electron injection layer 107 comprising an n-type chalcogenide semiconductor. By adding an n-type dopant, even when a transparent conductive oxide with a large work function is used as the cathode material, satisfactory electron injection properties can be obtained. Further, the electrical conductivity of the electron injection layer 107 can be improved, and even when the film thickness is increased a rise in the element driving voltage can be prevented. By this means, the range of film thicknesses which can be selected is expanded and there is greater freedom of optical design, and there is the advantageous result that cathode-anode short-circuit faults can be prevented.

As n-type dopants, one or more halogen elements selected from among fluorine, chlorine, bromine, and iodine can be selected, or one or more metal elements selected from among boron, aluminum, gallium and indium can be used.

Cathode:

In the past, metals, alloys, electrically conductive compounds and mixtures of these with small work functions (4.0 eV or less) have preferably been used as the electrode materials of the anode 108; but the anode 108 used in the present invention is required to be optically transmissive, and so transparent conductive oxide materials are included.

Transparent conductive oxide materials include the ITO (indium-tin oxide), IZO (indium-zinc oxide), IWO (indium-tungsten oxide), AZO (Al-doped zinc oxide), GZO (Ga-doped zinc oxide), and similar materials, previously introduced as anode materials.

Next, a method of manufacture of an organic EL element of the present invention is explained.

First, the anode 102 is formed on the substrate 101. When the anode 102 comprises a transparent conductive oxide material, high-reflectivity metal, amorphous alloy, or microcrystalline alloy, any deposition method including an evaporation deposition method, sputtering method or other methods known in this technical field can be used in formation.

Further, when the anode 102 comprises PEDOT:PSS or another conductive polymer material, any deposition method including a spin-coating method, ink jet method, printing, or other methods known in this technical field can be used in formation.

The hole injection layer 103, hole transport layer 104, light emission layer 105, and electron transport layer 106 all comprise either organic materials or organometal complexes, and in order to prevent degradation of these layers, a physical vapor phase growth method enabling formation of thin films is used, without employing a plasma process.

Formation of the electron injection layer 107 is performed using a physical vapor phase growth method not using plasma discharge, in order to prevent degradation of the adjacent electron transport layer 106 or light emission layer 105, comprising an organic material. As such a formation method, a resistive heating evaporation deposition method, electron beam evaporation deposition method or other vacuum evaporation deposition method, or a pulsed laser deposition (laser ablation) method, can suitably be used.

The cathode 108 can be manufactured by evaporation deposition, sputtering or similar. It is preferred that a sputtering method, ion plating method, or reactive plasma film deposition method, which are established as liquid crystal display manufacturing techniques and/or plasma display manufacturing techniques, or similar be used.

The invention is explained in detail using examples that follow.

### Example 1

On a glass substrate (50 mm long×50 mm wide×0.7 mm thick: 1737 glass manufactured by Corning), a DC magnetron sputtering method (target: In₂O₃+10 wt % ZnO, discharge gas: Ar+0.5% O₂, discharge pressure: 0.3 Pa, discharge power: 1.45 W/cm², substrate transport speed: 162 mm/min) was used to deposit IZO, and a photolithography method was used for forming into a stripe shape 2 mm wide, to form an anode of film thickness 110 nm and width 2 mm.

Next, a resistive heating evaporation deposition method was used to deposit 2-TNATA at an evaporation deposition rate of 1 Å/s onto the anode, to deposit 20 nm of a hole injection layer comprising 2-TNATA. Upon this was deposited, as a hole transport layer, 40 nm of NPB using a resistive heating evaporation deposition method at an evaporation deposition rate of 1 Å/s. Next, ADN was used as a light emission layer host, with a light emission dopant of 4,4′-bis(2-(4-(N,N-diphenylamino)phenyl)vinyl)biphenyl (DPAVBi), to deposit a light emission layer of thickness 30 nm, using an evaporation deposition rate of 1 Å/s for the AND and 0.03 Å/s for the DPAVBi. On the light emission layer was deposited 10 nm of Alq₃ at an evaporation deposition rate of 1 Å/s as the electron transport layer.

Next, 5 g of ZnS in particle form was placed into a boron nitride (BN) ceramic crucible, which was heated in a film deposition chamber (final vacuum 10⁻⁵ Pa), and an electron injection layer comprising 25 nm ZnS was evaporation deposited at a rate of 1 Å/s.

A DC magnetron sputtering method (target: In₂O₃+10 wt % ZnO, discharge gas: Ar+0.5% O₂, discharge pressure: 0.3 Pa, discharge power: 1.45 W/cm², substrate transport speed: 162 mm/min) was used to deposit IZO through a metal mask with a slit of width 1 mm opened above the electron injection layer, to form a cathode of film thickness 110 nm and width 2 mm. When using a metal mask to deposit IZO using the sputtering method, the metal mask and the substrate are not in close contact, so that IZO film deposition particles move laterally between the mask and substrate, and consequently the outline of the IZO film deposition pattern is blurred. Hence in order to form an electrode of width 2 mm, a metal mask with a slit of width 1 mm was used. Processes subsequent to the hole injection layer were performed without breaking the vacuum.

Then, the sample was moved into a nitrogen-substituted dry box, and therewithin an epoxy system adhesive was applied close to the four edges of a sealing glass plate (height 41 mm×width 41 mm×thickness 0.7 mm, OA-10 manufactured by Nippon Electric Glass), which was bonded to the sample so as to cover the organic EL layer, to obtain the transparent blue-light organic EL element of Example 1. During transfer to the dry box after cathode formation, processes were performed without exposing the sample to the outside atmosphere. As the characteristics of the organic EL element thus obtained, the voltage and current efficiency for a current density of 10 mA/cm² are shown in Table 1.

### Example 2

A supporting substrate of length 50 mm×width 50 mm×thickness 0.7 mm (1737 glass manufactured by Corning) was cleaned using an alkali cleaning liquid, and sufficiently rinsed with distilled water. Then, a DC magnetron sputtering method was used to deposit a silver alloy (APC-TR manufactured by Furuya Metal Co., Ltd.) onto the cleaned supporting substrate, to deposit a silver alloy film of thickness 100 nm. A spin-coating method was used to deposit on the silver alloy film a photoresist film (TFR-1250 manufactured by Tokyo Ohka Kogyo Co., Ltd.) of thickness 1.3 μm, and drying was performed for 15 minutes at 80° C. in a clean oven. The photoresist film was irradiated with ultraviolet light from a high-pressure mercury lamp passing through a photomask with a 2 mm wide stripe pattern, and developing was performed using a developing fluid (NMD-3 manufactured by Tokyo Ohka Kogyo Co., Ltd.), to manufacture a 2 mm wide photoresist pattern on the silvery alloy thin film.

Next, an etching solution for silver (SEA2 manufactured by Kanto Kagaku) was used to perform etching. Then, a stripping solution (stripping solution 104 manufactured by Tokyo Ohka Kogyo Co., Ltd.) was used to strip the photoresist pattern, to manufacture a metal layer comprising a stripe-shape portion of width 2 mm. On the metal layer was deposited a transparent conductive film of thickness 100 nm comprising indium-zinc oxide (IZO), using the same DC magnetron sputtering method as in Example 1. The same photolithography method as for the silver alloy thin film was used to perform patterning, to form a transparent conductive layer comprising a stripe-shape portion matching the pattern of the conductive layer, to obtain a reflective anode. Oxalic acid was used in IZO etching.

Next, the substrate with reflective anode formed was subjected to processing for 10 minutes at room temperature in an UV/O₃ cleaning apparatus provided with a low-pressure mercury lamp, after which the organic EL layer and cathode were formed similarly to Example 1, to manufacture a top-emission type blue-light organic EL element provided with a ZnS electron injection layer. The characteristics of the organic EL element thus obtained were measured similarly to Example 1, and results appear in Table 1.

### Example 3

Except for using MnS as the electron injection layer material, a procedure similar to that of Example 2 was used to manufacture a top-emission type blue-light organic EL element. The characteristics of the organic EL element obtained appear in Table 1.

### Comparative Example 1

Except for making the Alq₃ electron transport layer film thickness 35 nm, and forming an electron injection layer (1 nm) using the LiF conventionally used in bottom-emission elements instead of an n-type chalcogenide semiconductor electronic injection layer, a procedure similar to that of Example 2 was used to manufacture a blue-light organic EL element. The LiF layer was formed by placing powder material in a Mo crucible, and performing resist heating evaporation deposition at an evaporation deposition rate of 0.2 Å/s. The characteristics of the organic EL element obtained appear in Table 1.

### Comparative Example 2

Except for using indium oxide as the electron injection layer material, the same procedure as in Example 2 was used to manufacture a top-emission type blue light organic EL element. In forming the electron injection layer, indium oxide (In₂O₃) particle material was placed in a Mo crucible, and a resistive heating evaporation deposition method was used to form a 25 nm electron injection layer of indium oxide at an evaporation deposition rate of 1 Å/s. The characteristics of the organic EL element obtained appear in Table 1.

### Comparative Example 3

Except for not forming an electron transport layer of Alq₃ after light emission layer deposition, and forming a 35 nm ZnS electron injection/transport layer directly on the light emission layer, a procedure similar to that of Example 2 was used to manufacture a top-emission type blue light organic EL element. The characteristics of the organic EL element obtained appear in Table 1.

TABLE 1
Characteristics of EL elements at current density 10 mA/cm²

| | Electron | Electron | | Current | |
|---|---|---|---|---|---|
| | transport | injection | Voltage | efficiency | |
| | layer | layer | (V) | (cd/A) | |
| Comparative | Alq₃ | LiF | — | — | top |
| Example 1 | | | | | |
| Comparative | Alq₃ | InOₓ | 9.6 | 3.5 | top |
| Example 2 | | | | | |
| Comparative | — | ZnSₓ | 5.8 | 6.8 | top |
| Example 3 | | | | | |
| Example 1 | Alq₃ | ZnSₓ | 6.2 | 5.5 | transparent |
| Example 2 | Alq₃ | ZnSₓ | 6.2 | 11.5 | top |
| Example 3 | Alq₃ | MnSₓ | 5.6 | 12.1 | top |

In Comparative Example 1 using 1 nm of LiF as the electron injection layer, almost no current flows even when voltages of up to 10 V are applied, and no light was emitted. This result was obtained because at the time of formation of the IZO cathode by sputtering, oxidation degradation of the electron transport layer comprising Alq₃ could not be prevented, and the electron transport function was markedly impaired.

In Comparative Example 2, in which indium oxide was used as the electron injection layer, a voltage of approximately 10 V had to be applied despite passing a current of 10 mA/cm², whereas in the cases of the organic EL elements of Examples 1 to 3, the driving voltage was lowered to approximately 6 V. Moreover, the current efficiency was also greatly improved for Examples 2 and 3 compared with Comparative Example 2. Example 1 was a transparent organic EL element, and no reflective electrode existed, so that the current efficiency based on the brightness as measured from the film surface side was low, but even so, higher brightness was obtained than for Comparative Example 2.

In Comparative Example 3 in which ZnS was used as the electron injection layer and no electron transport layer was provided, the driving voltage was low compared with Example 2, but the efficiency was also greatly reduced. This suggests that by using an electron transport layer as in the present invention, an element which strikes a balance between driving voltage and light emission efficiency can be realized.

From the above, by employing an organic EL element configuration of the present invention using an electron injection layer comprising an n-type chalcogenide semiconductor, even when an upper cathode comprising a transparent conductive oxide material is formed using a sputtering method, an organic EL element capable of high light emission efficiency at low driving voltages can be provided.

1. An organic EL element, comprising, in the order recited:
a supporting substrate;
an anode provided on the supporting substrate;
an organic EL layer provided on the anode and having provided thereon, in the order recited:
a hole transport layer;
a light emission layer;
an electron transport layer,
an electron injection layer, in which the hole transport layer, the light emission layer, and the electron transport layer are comprised of organic materials, and the electron injection layer is comprised of an n-type chalcogenide semiconductor ham an optical band gap of 2.1 eV or greater; and
a cathode provided on the organic EL layer and comprised of a transparent conductive oxide.

2. The organic EL element according to claim 1, wherein the electron injection layer further comprises at least one halogen selected from the group consisting of fluorine, chlorine, bromine, and iodine.

3. The organic EL element according to claim 1, wherein the electron injection layer further comprises at least one metal element selected from the group consisting of boron, aluminum, gallium, and indium.

4. The organic EL element according to claim 1, wherein the n-type chalcogenide semiconductor is any one at zinc sulfide (ZnS), manganese sulfide (MnS), and zinc manganese sulfide (MnₓZn₁₋ₓS).

5. The organic EL element according to claim 1, wherein the n-type chalcogenide semiconductor is at least one rare earth n-type chalcogenide semiconductor selected from the group consisting of lanthanum sulfide (LaS), cerium sulfide (CeS), praseodymium sulfide (PrS), and neodymium sulfide (NdS).

6. A method of manufacturing the organic EL element according to claim 1, comprising:
forming the electron injection layer by a physical vapor phase growth method that is free of plasma discharge.

7. The method according to claim 6, wherein the physical vapor phase growth method is selected from the group consisting of a resistive heating evaporation deposition method, an electron beam evaporation deposition method, and a pulsed laser deposition (laser ablation) method.

8. The method of manufacture of an organic EL element according to claim 6, further comprising forming the cathode by sputtering.
